(19) United States
(12) Patent Application Publication
(10) Pub. No.: US 2011/0248389 A1
(43) Pub. Date: Oct. 13, 2011

(54) SEMICONDUCTOR DEVICE AND MANUFACTURING METHOD THEREOF

(75) Inventors: Chiko YORITA, Fujisawa (JP); Tsutomu HARA, Yokohama (JP); Hiroshi OKABE, Koganei (JP); Tomonori TANOUE, Machida (JP); Yuji SHIRAI, Kanagawa (JP)

(73) Assignee: RENESAS ELECTRONICS CORPORATION, Kanagawa (JP)

(21) Appl. No.: 13/050,288

(22) Filed: Mar. 17, 2011

(30) Foreign Application Priority Data
Mar. 18, 2010 (JP) JP2010-061750

(51) Int. Cl. H01L 23/552; H01L 21/82; H01L 23/48

(52) U.S. Cl. 257/659; 257/734; 438/113; 257/E23.01; 257/E23.114; 257/E21.602

(57) ABSTRACT

An upper module board on which an integrated chip component with a low upper temperature limit is mounted and a lower module board on which a heat-generating semiconductor chip, a single chip component and an integrated chip component are mounted are electrically and mechanically connected via a plurality of conductive connecting members, and these are sealed together with mold resin. In such a circumstance, a shield layer made up of a stacked film of a Cu plating film and a Ni plating film is formed on side surfaces of the upper and lower module boards and surfaces (upper and side surfaces) of the mold resin, thereby realizing the electromagnetic wave shield structure.

### CROSS-REFERENCE TO RELATED APPLICATION

The present application claims priority from Japanese Patent Application No. 2010-061750 filed on Mar. 18, 2010, the content of which is hereby incorporated by reference to this application.

### TECHNICAL FIELD OF THE INVENTION

The present invention relates to a semiconductor device and a manufacturing technique thereof, and more particularly to a technique effectively applied to a high-frequency power amplifier module, a semiconductor device in which the high-frequency power amplifier module is mounted on a mounting board (mother board) and a manufacturing method thereof.

### BACKGROUND OF THE INVENTION

Japanese Patent Application Laid-Open Publication No. 2005-217348 (Patent Document 1) discloses a circuit module including: first and second circuit boards on which other electronic components are mounted; and a relay board which has concave portions and a frame portion and in which electronic components are mounted and lead-out lines from the other electronic components are provided in the concave portions and land portions for connecting the first circuit board and the second circuit board are formed on upper and lower surfaces of the frame portion, and the circuit module has a structure in which the first circuit board and the second circuit board are connected via the relay board in a three-dimensional manner.

Japanese Patent Application Laid-Open Publication No. 6-013541 (Patent Document 2) discloses a stackable three-dimensional multi-chip module having a structure in which upper and lower chip carriers are connected with solder balls disposed in the periphery of upper and lower surfaces of the boards of the carriers and the device is sealed by use of a lid of the lower chip. Furthermore, a height of the lid plays a roll of a natural standoff protrusion between the levels of the carriers, and an interconnecting structure with a function of solder joint having a sand-clock shape capable of maximizing the durability life of the joint is disclosed.

Japanese Patent Application Laid-Open Publication No. 2004-172176 (Patent Document 3) discloses a circuit module including: an insulating layer covering a plurality of components disposed on a board; a ground electrode provided on the board in a state of being exposed from the insulating layer; and a shield layer formed outside the insulating layer and connected to the ground electrode, in which the end faces of the board and the shield layer are located on the same plane.

Japanese Patent Application Laid-Open Publication No. 2006-286915 (Patent Document 4) discloses a circuit module including: a circuit board having a wiring pattern and a ground layer; a group of electronic components mounted on a mounting surface of the circuit board; an insulating resin layer for sealing the group of electronic components; and a conductive resin layer formed on a surface of the insulating resin layer and containing metal in a flake form.

Japanese Patent Application Laid-Open Publication No. 2005-109306 (Patent Document 5) discloses an electronic component package including: a circuit board having a ground pattern; mounted components made up of electronic components mounted on an upper surface of the circuit board; a sealing body made of epoxy resin containing inorganic filler for sealing the mounted components; and an electromagnetic wave shield layer (electroless copper plating layer, electrolytic copper plating layer and coating layer) formed on a surface of the sealing body and grounded to the ground pattern.

Japanese Patent Application Laid-Open Publication No. 2005-333047 (Patent Document 6) discloses a manufacturing method of a circuit component built-in module in which, after a plurality of component-mounted units formed on a board are molded with insulating resin and then hardened, trenches having a depth reaching about a half of the thickness of the board are processed to a lattice pattern and further a plating surface layer is formed, and then, the part of the board corresponding to the rest of the thickness is removed, thereby obtaining single modules.

Japanese Patent Application Laid-Open Publication No. 2004-088021 (Patent Document 7) discloses a manufacturing method of a three-dimensional mounted module in which a component is mounted on one surface of a board, a heat-generating component is disposed on a rear side of the board, and a rear surface of the component having a large power consumption (heat-generating component) is disposed on a heat dissipation plate for the purpose of reducing an area of the mounting board and ensuring the heat dissipation between components.

Japanese Patent Application Laid-Open Publication No. 2005-340642 (Patent Document 8) discloses a manufacturing method of an electronic circuit unit in which, in a circuit board on one surface of which a heat generating component is disposed and on the other surface of which a characteristic fluctuated component whose characteristics are greatly affected by a high temperature is disposed, a void portion is provided between the heat generating component and the characteristic fluctuated component and the void portion has a heat conductivity lower than that of the circuit board for the purpose of preventing the characteristic fluctuation due to the heat generating component and achieving the thickness reduction.

### SUMMARY OF THE INVENTION

At present, the components mounted on a mounting board of a mobile communication device such as a mobile phone are mounted in respective areas separated for each functional block such as a high-frequency module, a front end module, a communication module for transmission and reception and a power supply module, and a metal electromagnetic wave shield is provided according to individual needs.

The inventors of the present invention have been examining the technique in which two or more modules each obtained by integrating respective functions of a high-frequency module, a front end module including a filter and a communication module for transmission and reception into one module and arranged in a plane are further integrated into one module, thereby achieving the high-density mounting for further size reduction while ensuring the thermal separation structure between the heat generating component and the heat sensitive component.

An object of the present invention is to provide a technique capable of achieving the size reduction of an integrated module in which a plurality of modules are mounted at high density.

The above and other objects and novel characteristics of the present invention will be apparent from the description of the present specification and the accompanying drawings.

The following is a brief description of an outline of the typical invention disclosed in the present application.

(1) A semiconductor device according to the present invention includes: a first circuit board in which a wiring layer in a part of an inner-layer wiring is used as a ground wiring; a plurality of first mounted components mounted on a first component mounting surface of the first circuit board; a second circuit board stacked on the first component mounting surface of the first circuit board; a plurality of second mounted components mounted on a second component mounting surface of the second circuit board; a plurality of connecting members which mechanically and electrically connect the first circuit board and the second circuit board; and first resin which seals the first circuit board, the second circuit board, the plurality of first mounted components and the plurality of second mounted components together, and the plurality of first mounted components include a first component which generates heat, the plurality of second mounted components include a second component whose characteristics are changed by the heat generated from the first component, and the first component and the second component are disposed so as to be thermally separated.

(2) A manufacturing method of a semiconductor device according to the present invention includes the steps of: (a) preparing a first board base in which a wiring layer in a part of an inner-layer wiring is used as a ground wiring and one or more structures including a heat dissipation via, a heat dissipation metal body and a heat dissipation metal core layer are formed in a first circuit board, the first board base being partitioned into a plurality of the first circuit boards; (b) mounting a plurality of first mounted components on a first component mounting surface of the first circuit board; (c) preparing a second board base partitioned into a plurality of second circuit boards each having the same planar shape as that of the first circuit board; (d) mounting a plurality of second mounted components on a second component mounting surface of the second circuit board; (e) after the step (b) and after the step (d), mechanically and electrically connecting the first board base and the second board base via a plurality of connecting members so that the second circuit board is stacked on the first component mounting surface of the first circuit board; (f) after the step (e), sealing the first board base, the second board base, the plurality of first mounted components and the plurality of second mounted components together with first resin; (g) dicing the first resin, the first board base and the second board base along the shape of the first circuit board and the second circuit board until the first board base is partially cut in a thickness direction, thereby forming trenches having side surfaces on which the ground wirings are exposed; (h) forming a metal shield member so as to cover the side surfaces of the trenches and the first resin and come into contact with the ground wirings; and (i) after the step (h), dicing the remaining first base body along the trenches, thereby dividing it into individual semiconductor devices.

The effects obtained by typical embodiments of the invention disclosed in the present application Will be briefly described below.

It is possible to achieve the size reduction of an integrated module in which a plurality of modules are mounted at high density.

### BRIEF DESCRIPTIONS OF THE DRAWINGS

FIG. 1 is a circuit diagram showing an example of a circuit of a power amplifier in a high-frequency module used in a digital mobile phone having a semiconductor device according to an embodiment of the present invention;

FIG. 2 is a cross-sectional view showing an example of a primary mounting of the high-frequency module in the digital mobile phone having the semiconductor device according to the embodiment of the present invention;

FIG. 3 is a plan view for describing the positional relation between a module board and connecting members for connecting upper and lower module boards in the semiconductor device according to the embodiment of the present invention;

FIG. 4 is a plan view for describing the positional relation between a module board and the connecting members for connecting upper and lower module boards in the semiconductor device according to the embodiment of the present invention;

FIG. 5 is a plan view for describing the positional relation between the module boards and the connecting members for connecting upper and lower module boards in the semiconductor device according to the embodiment of the present invention;

FIG. 6 is an explanatory diagram showing an expansion of an area of a module board in the case where the same semiconductor chips and chip components as those of the module board in the semiconductor device according to the embodiment of the present invention are mounted on one module board;

FIG. 7 is a cross-sectional view of the principal part for describing the connecting member for connecting the upper and lower module boards in the semiconductor device according to the embodiment of the present invention;

FIG. 8 is a flowchart for describing a part of the manufacturing process of the semiconductor device according to the embodiment of the present invention;

FIG. 9 is a cross-sectional view of the principal part for describing the manufacturing process of the semiconductor device according to the embodiment of the present invention;

FIG. 10 is a cross-sectional view of the principal part in the manufacturing process of the semiconductor device continued from FIG. 9;

FIG. 11 is a cross-sectional view of the principal part in the manufacturing process of the semiconductor device continued from FIG. 10;

FIG. 12 is a cross-sectional view of the principal part in the manufacturing process of the semiconductor device continued from FIG. 11;

FIG. 13 is a cross-sectional view of the principal part in the manufacturing process of the semiconductor device continued from FIG. 12;

FIG. 14 is a cross-sectional view of the principal part in the manufacturing process of the semiconductor device continued from FIG. 13;

FIG. 15 is a cross-sectional view showing an example of a primary mounting of a high-frequency module in a digital mobile phone having a semiconductor device according to another embodiment of the present invention;

FIG. 16 is a cross-sectional view showing an example of a primary mounting of a high-frequency module in a digital mobile phone having a semiconductor device according to another embodiment of the present invention;

FIG. 17 is a cross-sectional view showing an example of a primary mounting of a high-frequency module in a digital mobile phone having a semiconductor device according to another embodiment of the present invention;

FIG. 18 is a cross-sectional view showing an example of a heat dissipation structure of a high-frequency module in a digital mobile phone having a semiconductor device according to another embodiment of the present invention;

FIG. 19 is a cross-sectional view showing an example of a heat dissipation structure of a high-frequency module in a digital mobile phone having a semiconductor device according to another embodiment of the present invention;

FIG. 20 is a cross-sectional view showing an example of a heat dissipation structure of a high-frequency module in a digital mobile phone having a semiconductor device according to another embodiment of the present invention; and

FIG. 21 is a cross-sectional view showing an example of a heat dissipation structure for dissipating the heat of a high-frequency module to a chassis of a mobile phone in a digital mobile phone having a semiconductor device according to another embodiment of the present invention.

### DESCRIPTIONS OF THE PREFERRED EMBODIMENTS

Prior to the detail description of the embodiments of the present invention, meaning of the terms used in the following embodiments will be described as follows.

GSM (Global System for Mobile Communication) means one of wireless communication systems or a standard used for digital mobile phones. There are three radio wave frequency bands used in GSM, and GSM using 900 MHz band is referred to as GSM 900 or simply GSM, GSM using 1800 MHz band is referred to as GSM 1800, DCS (Digital Cellular System) 1800 or PCN (Personal Communication Network), and GSM using 1900 MHz band is referred to as GSM 1900, DCS 1900 or PCS (Personal Communication Services). Note that GSM 1900 is mainly used in North America. GSM 850 using 850 MHz band is sometimes used in North America in addition to GSM 1900. Furthermore, W-CDMA (Wideband Code Division Multiple Access) is frequently called UMTS (Universal Mobile Telecommunications System) or 3G (3rd Generation), and frequency bands of 850 MHz band, 900 MHz band and 1900 MHz band are used.

As described above, the frequency band used for the GSM system mobile phone network includes four types such as 850 MHz band, 900 MHz band, 1800 MHz band and 1900 MHz band. Out of the high-frequency modules, the module that supports all of the four bands is referred to as a quad-band product, and the module that supports three bands is referred to as a tripe-band product. In GMSK (Gaussian filtered Minimum Shift Keying) modulation system, the phase of a carrier wave is shifted by using the system used for the communication of speech signals in accordance with the transmission data. Also, in EDGE (Enhanced Data GSM Environment) modulation system, amplitude shift is further added to the phase shift of the GMSK modulation by the system used for data communication.

Furthermore, in the embodiments below, out of a plurality of surface mounted components that are mounted on one module board, a chip in which one or plural active elements are formed on one chip substrate is referred to as a semiconductor chip, and a chip in which a passive element such as a capacitor, an inductor or a register is formed on one chip substrate is referred to as a chip component. Also, a chip in which one passive element is formed on one chip substrate is referred to as a single chip component, a chip in which a plurality of passive elements are formed on one chip substrate is referred to as an integrated chip component, and they are separately described as an integrated chip component and a single chip component when they need to be distinguished.

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Further, in the embodiments described below, it goes without saying that the components (including element steps) are not always indispensable unless otherwise stated or except the case where the components are apparently indispensable in principle. Also, even when mentioning that constituent elements or the like are “made of A” or “made up of A” in the embodiments below, elements other than A are of course not excluded except the case where it is particularly specified that A is the only element thereof.

Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Still further, when the materials and the like are mentioned, the specified material is a main material unless otherwise stated or except the case where it is not so in principle or situationally, and the secondary components, additives, additional components and the like are not excluded. For example, a silicon material includes not only the case of pure silicon but also secondary and ternary alloys (for example, SiGe) and the like formed of additive impurities and silicon as the main component unless otherwise stated.

Also, components having the same function are denoted by the same reference symbols throughout the drawings for describing the embodiments, and the repetitive description thereof will be omitted in principle.

Also, in some drawings used in the following embodiments, hatching is partially used even in a plan view so as to make the drawings easy to see.

Embodiments of the present invention will be described below in detail with reference to the accompanying drawings.

### First Embodiment

In the first embodiment, the case where the present invention is applied to a digital mobile phone (mobile communication device) which transmits information by use of a multi-mode network of, for example, DCS 1800 and W-CDMA system will be described.

An example of the system configuration of the digital mobile phone according to the present embodiment will be described. The present embodiment can be applied to a device including a power amplifier, an antenna for transmitting and receiving signal waves, a front end device, a base band circuit which converts a speech signal into a base band signal, converts a received signal into a speech signal and generates a modulation system switching signal and a band switching signal, a modulation/demodulation circuit which downconverts and demodulates a received signal to generate a base band signal and demodulates a transmitting signal, and a filter which removes a noise and an interfering wave from a received signal.

A switching signal of a switch circuit is supplied from the base band circuit. The base band circuit is made up of a plurality of semiconductor integrated circuits such as a DSP (Digital Signal Processor), a microprocessor and a semiconductor memory.

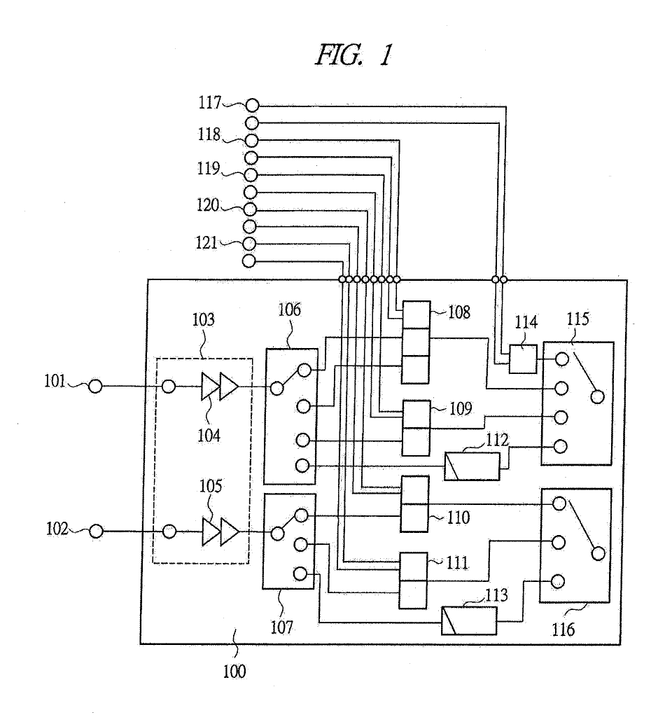

FIG. 1 shows an example of a circuit of a power amplifier in a high-frequency module.

A power amplifier 103 in a high-frequency module 100 can use four frequency bands of, for example, GSM 850, GSM 900, GSM 1800 and GSM 1900 (multi-mode system), and can use two communication systems of GMSK modulation system and EDGE modulation system at the respective frequency bands.

This power amplifier 103 includes a power amplifier circuit 104 for GSM 850 and GSM 900, a power amplifier circuit 105 for GSM 1800 and GSM 1900 (DCS 1800), and peripheral circuits for controlling and correcting the amplification operation of the power amplifier circuits 104 and 105. The power amplifier circuits 104 and 105 have respective amplifier stages. In the first embodiment, elements constituting the power amplifier circuits 104 and 105 described above are provided in one heat-generating semiconductor chip IC1.

In the device of the present embodiment, signals input from a high band input terminal 101 and a low band input terminal 102 are amplified by the power amplifier circuits 104 and 105 in the power amplifier 103 and pass through switches 106 and 107, and then, respective signals pass through a filter 108 for BAND 1/BAND 4, a filter 109 for BAND 2 (GSM 1900 MHz band), a filter 110 for BAND 5 (GSM 850 MHz band), a filter 111 for BAND 8 (GSM 900 MHz band), a filter 112 for DCS 1800 HMz band and PCS 1900 MHz band and a filter 113 for GSM 850 MHz band and GSM 900 MHz band, are switched by switches 115 and 116, and are output to respective output terminals such as an output terminal 117 for GSM 1800 MHz band, an output terminal 118 for BAND 1/BAND 4 (1900 MHz band/2000 MHz band), an output terminal 119 for BAND 2 (GSM 1900 MHz band), an output terminal 120 for BAND 5 (GSM 850 MHz band) and an output terminal 121 for BAND 8 (GSM 900 MHz band) through a filter 114 in the case of GSM 1800 MHz band.

The peripheral circuits include a control circuit, a bias circuit for applying a bias voltage to the amplifier stages and others. In the first embodiment, when a power supply control circuit generates a first power supply voltage based on an output level specification signal supplied from a base band circuit outside the power amplifier 103, a bias voltage generating circuit generates a control voltage based on the power supply voltage generated in the power supply control circuit. The base band circuit is a circuit for generating an output level specification signal. This output level specification signal is a signal for specifying the output level of the power amplifier circuits 104 and 105, and it is generated based on the output level depending on the distance between the mobile phone and the base station, that is, the intensity of the radio wave. In the first embodiment, the element constituting the peripheral circuit like this is also provided in one heat-generating semiconductor chip IC1.

Next, representative elements out of the elements constituting the power amplifier 103 will be described. The power amplifier 103 in which the power amplifier circuits 104 and 105 are made up of LDMOSFETs (Laterally Diffused Metal Oxide Semiconductor Field Effect Transistor) is formed in the heat-generating semiconductor chip IC1. The power amplifier circuit is made up of LDMOSFET in the first embodiment, but the present invention is not limited to this and the power amplifier circuit can be made up of, for example, hetero-junction bipolar transistor (HBT).

The heat-generating semiconductor chip IC1 in which the power amplifier 103 is formed is mounted on a module board with the main surface thereof being directed downward (face down), and external terminals of the heat-generating semiconductor chip IC1 and board terminals formed on a component mounting surface of the module board are electrically connected by a bonding material, for example, bump electrodes BE made of solder.

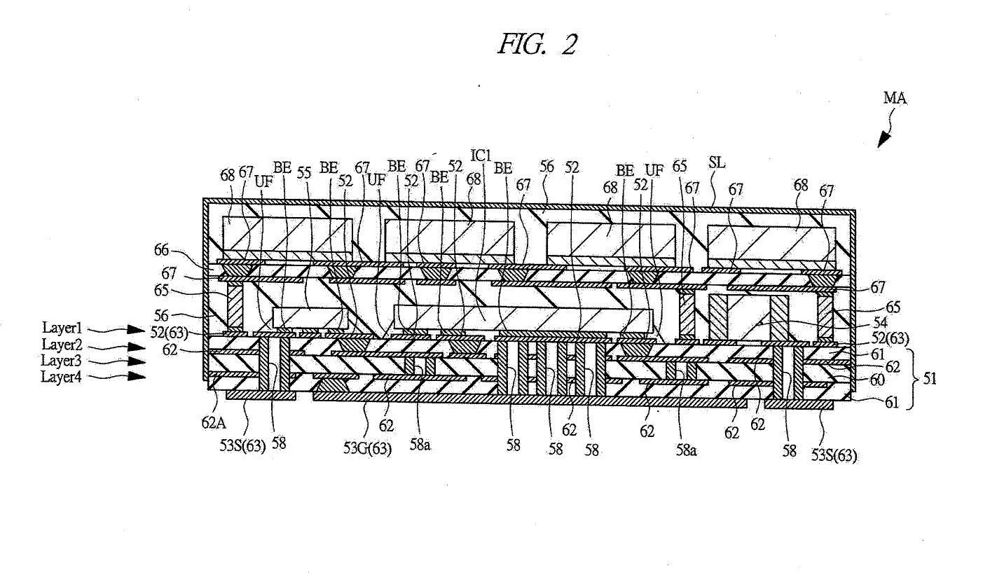

Next, the structure of a module MA after a primary mounting in which surface mounted components are mounted on the module board will be described. FIG. 2 is a cross-sectional view of the principal part showing an example of the primary mounting of the module MA according to the first embodiment. The structure in which the above-described front end device 1 and a power amplifier PM are assembled into one module MA is shown here, but it is needless to say that the present invention is not limited to this. For example, the front end device 1 and the power amplifier PM may be provided as separate high-frequency modules. Also, the description will be made here with using the heat-generating semiconductor chip IC1 having the power amplifier PM in which amplifier stages are made up of LDMOSFETs as an example, but a semiconductor chip having a power amplifier in which amplifier stages are made up of HBTs may also be used.

As shown in FIG. 2, in the module MA, a PCB (Printed Circuit Board) having a multi-layered wiring structure in which a plurality of insulating plates are stacked and integrated is used as a module board 51. Board terminals 52 made of, for example, a copper (Cu) film and wirings are patterned and formed on a component mounting surface of the module board 51, and electrodes 53G and 53S made of, for example, a Cu film are patterned and formed on a rear surface of the module board 51.

As the example of the surface mounted components mounted on the component mounting surface of the module board 51, FIG. 2 shows the heat-generating semiconductor chip IC1 in which active elements are formed, a single chip component 54 in which one passive element is formed on one chip substrate, and an integrated chip component 55 in which a plurality of passive elements are formed on one chip substrate. The above-described power amplifier PM is formed in the heat-generating semiconductor chip IC1. A plurality of external terminals formed on the main surface of the heat-generating semiconductor chip IC1 are connected to the corresponding board terminals 52 of the module board 51 by a bonding material. In this case, bump electrodes BE are used as the bonding material. Also, underfill resin UF is filled and sealed in a space between the heat-generating semiconductor chip IC1 and the module board 51.

Furthermore, these surface mounted components are covered with highly elastic sealing mold rein 56. The mold resin 56 is, for example, highly elastic epoxy rein, and an allowable range of the elastic modulus thereof is preferably 2 GPa or higher at a temperature of 180° C. or higher.

The bump electrodes BE formed on an element forming surface of the heat-generating semiconductor chip IC1 are bonded to board terminals 52 for mounting the chip formed on the component mounting surface of the module board 51, whereby the heat-generating semiconductor chip IC1 is fixed onto the module board 51.

Out of the bump electrodes BE formed on the heat-generating semiconductor chip IC1, the bump electrode BE electrically connected to a source electrode 40 is electrically and thermally bonded to an electrode 53G formed on a rear surface of the module board 51 through a conductive material in a plurality of heat dissipation vias 58 formed so as to penetrate from the component mounting surface to the rear surface of the module board 51. Reference potential (for example, ground potential GND of about 0V) is supplied to this electrode 53G. More specifically, the reference potential supplied to the electrode 53G of the rear surface of the module board 51 is supplied to the rear surface of the heat-generating semiconductor chip IC1 through the heat dissipation via 58 and the board terminal 52. Furthermore, the heat generated by the operation of the heat-generating semiconductor chip IC1 is transmitted from the element forming surface of the heat-generating semiconductor chip IC1 to the electrode 53G of the rear surface of the module board 51 through the board terminal 52 and the heat dissipation via 58 and is then dissipated. The electrodes 53S formed in the outer periphery of the rear surface of the module board 51 indicate signal electrodes.

The single chip component 54 is a surface mounted component in which a passive element such as a capacitor, an inductor, a register or a ferrite bead is formed on one chip substrate. The ferrite bead has a structure in which an inner electrode for conduction is embedded in a ferrite element, and the ferrite works as a magnetic body to absorb the high-frequency current component to be a cause of electromagnetic interference (EMI) noise. The single chip component 54 is mounted on the module board 51 with the rear surface thereof being faced to the component mounting surface of the module board 51, and connection terminals formed on both ends of the single chip component 54 are connected by solder to the board terminals 52 formed on the component mounting surface of the module board 51. Pb-free solder containing no Pb, for example, Sn-3Ag (silver) solder is used for this solder connection. The distance between the rear surface of the single chip component 54 and the component mounting surface of the module board 51 is, for example, about 10 μm, and the sealing resin 56 is filled in the space therebetween without forming voids.

The Pb-free solder is used as the solder material used for the solder connection of the single chip component 54 in the description above, but the solder material is not limited to this and various materials can be used, and for example, Sn containing Pb (hereinafter, referred to as Pb—Sn solder) can be used. However, the Pb-free solder is preferable in consideration of the restriction of Pb in Europe.

The integrated chip component 55 is a surface mounted component in which a plurality of passive elements such as a low-pass filter are formed on one chip substrate. The integrated chip component 55 is flip-chip connected to the module board 52 with the main surface thereof being faced to the component mounting surface of the module board 51, and connection terminals formed on the main surface of the integrated chip component 55 are connected to board terminals 52 formed on the component mounting surface of the module board 51 via the bump electrodes BE. The underfill resin UF is filled and sealed in the space between the main surface of the integrated chip component 55 and the component mounting surface of the module board 51.

The module board 51 is made up of a core material 60 and insulating materials called prepregs 61 sandwiching the core material 60 from above and below. Inner-layer Cu films 62 (second layer wiring Layer2 and third layer wiring Layer3) are patterned and formed on and below the core material 60, and these inner-layer Cu films 62 are sandwiched between the prepregs 61. Further, the second layer wiring Layer2 and the third layer wiring Layer3 are electrically connected via conductive films formed on sidewalls of the through holes 58a formed in the core material 60.

The wiring pattern (second layer wiring Layer2) of the inner-layer Cu film 62 is formed between the core material 60 and the prepreg 61 on the component mounting surface side of the module board 51. The wiring pattern (third layer wiring Layer3) of the inner-layer Cu film 62 is formed between the core material 60 and the prepreg 61 on the rear surface side of the module board 51. The thickness of the inner-layer Cu film 62 is, for example, about 0.02 mm, and the thickness of the prepreg 61 is, for example, about 0.06 mm.

Furthermore, the wiring pattern (first layer wiring Layer1) of an outer-layer Cu film 63 including the above-described board terminals 52 and wirings is patterned and formed on the outer surface of the prepreg 61 on the component mounting surface side. On the component mounting surface, the surface mounted components, for example, the heat-generating semiconductor chip IC1 and the chip component 64 (including the single chip component 54 and the integrated chip component 55 described above) are mounted. The outer-layer Cu film 63 (fourth layer wiring Layer4) including the electrodes 53G and 53S described above is patterned and formed on the outer surface of the prepreg 61 on the rear surface side.

The wiring pattern (fourth layer wiring Layer4) of the outer-layer Cu film 63 is formed on the outer surface of the prepreg 61 on the rear surface side of the module board 51. The thickness of the outer-layer Cu film 63 is, for example, about 0.02 mm.

A plating film having a stacked structure made up of, for example, a Ni layer and an Au layer formed in this order from below by the plating method is formed on the surface of the outer-layer Cu film 63. Furthermore, except for the region where the heat-generating semiconductor chip IC1 or the surface mounted component including the chip component 64 is mounted, the outer-layer Cu film 63 is covered with solder resist (not shown). The thickness of the solder resist is, for example, about 0.025 to 0.05 mm.

The two inner-layer Cu films 62 located on and below the core material 60 (second layer wiring Layer2 and third layer wiring Layer3) or the inner-layer Cu films 62 and the outer-layer Cu films 63 (first layer wiring Layer1 and second layer wiring Layer2 or third layer wiring Layer3 and fourth layer wiring Layer4) are electrically connected via heat dissipation vias 58 filled with Cu films penetrating through the core material 60 or the prepregs 61. The core material 60, the prepregs 61 and the solder resist are made of, for example, epoxy resin.

Also, a part of the second layer wiring Layer2 (part illustrated by the inner-layer Cu film 62A) is formed up to the outer periphery of the core material 60 and is electrically connected to a shield layer SL described later. The inner-layer Cu films 62 and 62A electrically connected to the shield layer SL are ground wirings, and are electrically connected to the wiring pattern (fourth layer wiring Layer4) of the outer-layer Cu film 63 formed outside the prepreg 61 on the rear surface side via the heat dissipation vias 58 formed in the core material 60 and the prepreg 61.

A module board 66 is stacked on the module board 51 via conductive connecting members 65. The material and structure of the connecting member 65 will be described later. The module board 66 is made of a core material equal to the core material 61 in the module board 51, and it has a rear surface faced to the module board 51 and a component mounting surface on a side reverse to the rear surface. Board terminals 67 equal to the board terminals 52 and the wiring of the module board 51 are formed on the component mounting surface and the rear surface of the module board 66. One end of the connecting member 65 is connected to the board terminal 52 on the component mounting surface of the module board 51, the other end thereof is connected to the board terminal 67 on the rear surface of the module board 66, and the module board 51 and the module board 66 are electrically connected via the connecting member 65. More specifically, various signals are transmitted and power supply potential and reference potential are supplied between the module board 51 and the module board 66 through the connecting members 65. Furthermore, since the above-described mold resin 56 is supplied so as to fill the space between the module board 51 (heat-generating semiconductor chip IC1, single chip component 54 and integrated chip component 55) and the module board 66, it is possible to prevent the occurrence of the warpage of the module board 66 due to the load and stress acting on the module board 66 in this structure.

In the first embodiment, integrated chip components 68 with a low upper temperature limit, in which a plurality of passive elements are formed on one chip substrate, are shown as an example of the surface mounted component mounted on the component mounting surface of the module board 66. A surface acoustic wave (SAW) filter is formed on each of the integrated chip components 68 with a low upper temperature limit.

The integrated chip components 68 with a low upper temperature limit mounted on the component mounting surface of the module board 66 are arranged and covered with the mold resin 56 so as not to be subjected to the element deformation due to the heat of the above-described heat-generating semiconductor chip IC1. The mold resin 56 filled in the space between the module board 51 and the module board 66 and the mold resin 56 covering the component mounting surface (the integrated chip components 68 with a low upper temperature limit) of the module board 66 are formed in the same process, and the details thereof will be described later.

The shield layer SL is formed on a part of the side surfaces of the module board 51, side surfaces of the module board 66 and surfaces (upper surface and side surfaces) of the mold resin 56.

The shield layer SL is formed by the electroless plating method. In the electroless plating method, a plating film can be selectively deposited on a catalytically active surface without using external power supply. For example, as described in “textbook on plating” edited by Electroplating Research Group, published by Nikkan Kogyo Shimbun Ltd. 1986, in the autocatalytic electroless Cu plating method, the deposition reaction of Cu is continued by the oxidation reaction of reductant agent. Also, by means of the process using activation solution containing Pb, the plating film can be uniformly formed even on a nonconductive material such as mold resin and on a part with complex shapes. Therefore, a uniform shield layer SL can be formed by the electroless plating method even on the surfaces (upper surface and side surfaces) of the mold resin 56 which seals the surface mounted components mounted in the module MA. As a result, since a desired shield effect can be achieved with a minimum necessary metal material, there is an advantage of cost reduction of the product.

In the first embodiment, the shield layer SL is made up of a stacked film including a first film having a function of shielding the electromagnetic wave and formed by the electroless plating method, for example, a Cu film and a second film having an anticorrosion function and formed on the Cu film by the electroless plating method, for example, a Ni film.

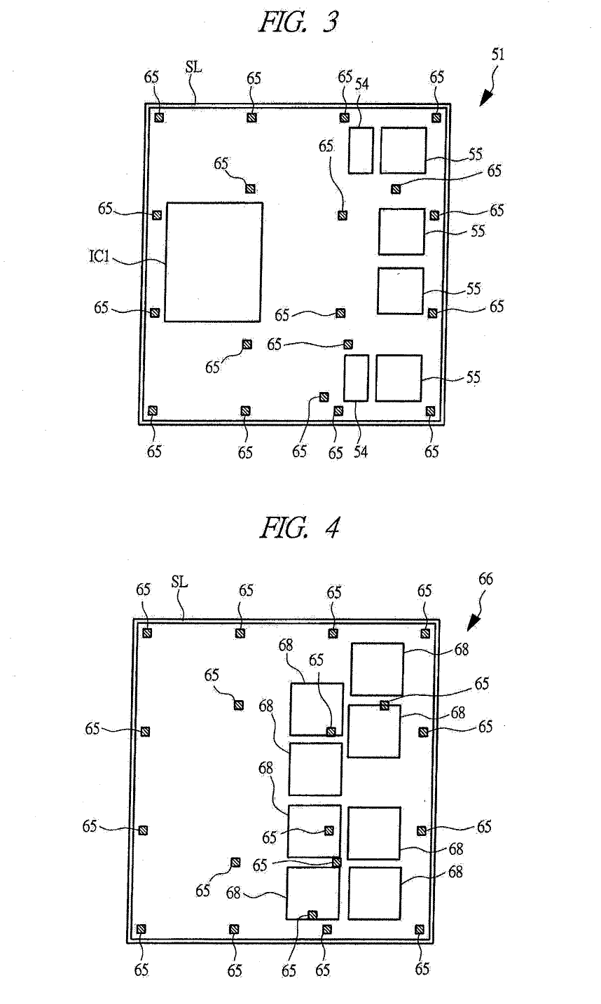

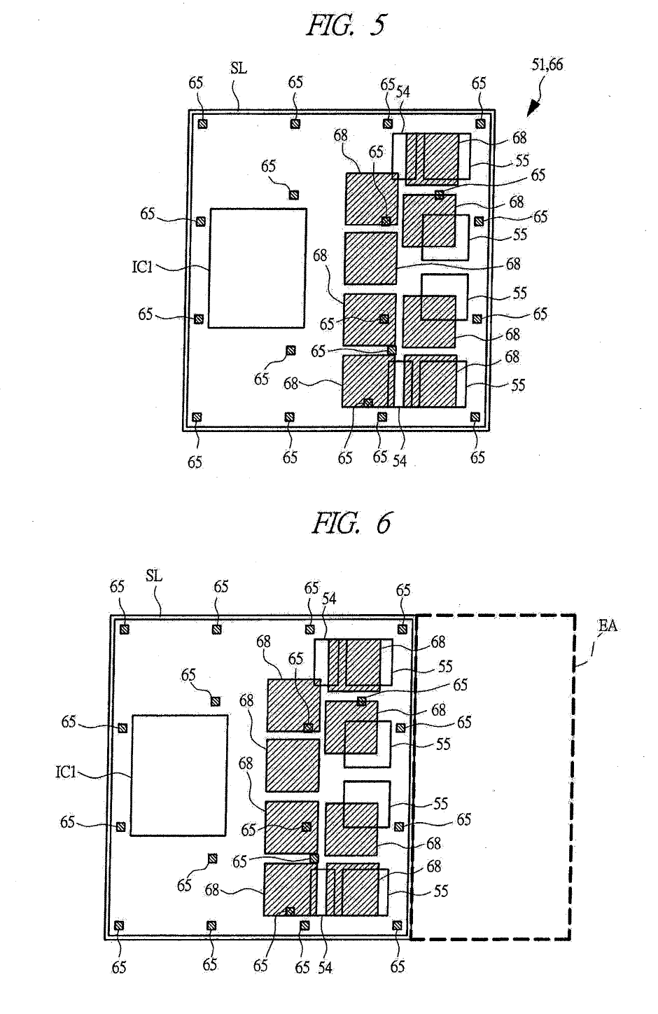

Next, connecting positions of the module boards 51 and 66 and the connecting members 65 in a plane will be described with reference to FIG. 3 to FIG. 6. FIG. 3 is a plan view showing the lower stage of the module seen from above. FIG. 4 is a plan view showing the upper stage of the module seen from above. Note that FIG. 3 shows the connecting positions of the module board 66 and the connecting members 66 in a plane, FIG. 5 illustrates the layout obtained by overlapping the layouts of FIG. 3 and FIG. 4, and the integrated chip components 68 with a low upper temperature limit mounted on the component mounting surface of the module board 66 are shown with hatching so as to make the layout easy to see in FIG. 6. Further, for the comparison with the module MA of the first embodiment, FIG. 6 also shows the expansion of the area of the module board in the case where the same semiconductor chips and chip components as those of the module MA are mounted on one module board.

As shown in FIG. 3, the connecting members 65 are provided at the positions not overlapped with the heat-generating semiconductor chip IC1, the single chip components 54 and the integrated chip components 55 on the component mounting surface of the module board 51. On the other hand, as shown in FIG. 4, since the connecting members 65 are connected to the rear surface of the module board 66, the connecting members 65 can be provided even at the positions planarly overlapped with the integrated chip components 68 with a low upper temperature limit mounted on the component mounting surface of the module board 66. As a result, since the areas of the module boards 51 and 66 can be reduced, the reduction in the area of the module MA is also achieved. Furthermore, as shown in FIG. 5, the integrated chip components 68 with a low upper temperature limit mounted on the component mounting surface of the upper module board 66 can be disposed even at the positions planarly overlapped with the heat-generating semiconductor chip IC1, the single chip components 54 and the integrated chip components 55 of the lower module board 51. Accordingly, the areas of the module boards 51 and 66 can be further reduced.

Here, an area denoted by EA (shown by dotted lines) in FIG. 6 shows the area expanded in comparison with the module boards 51 and 66 when all of the heat-generating semiconductor chip IC1, single chip components 54, integrated chip components 55 and integrated chip components 68 with a low upper temperature limit are mounted on one module board. As can be seen in FIG. 6, in the case of the stacked structure of the module boards 51 and 66 like in the module MA of the first embodiment, the area of the module MA can be significantly reduced to “about 58%” compared with the case of using only one module board.

Here, if the heat-generating semiconductor chip IC1 is disposed in the second layer so as to be overlapped on the integrated chip component 68 with a low upper temperature limit, the temperature of the integrated chip component 68 with a low upper temperature limit exceeds its upper temperature limit due to the influence of the heat of the heat-generating semiconductor chip IC1 in the operation of the module, and the integrated chip component 68 cannot deliver its performance or cannot be operated. For its prevention, as shown in FIG. 5, the integrated chip component 68 with a low upper temperature limit is disposed on the opposite side of the upper stage so as to be thermally separated from the heat-generating semiconductor chip IC1, thereby simultaneously achieving the thermal separation and the module size reduction.

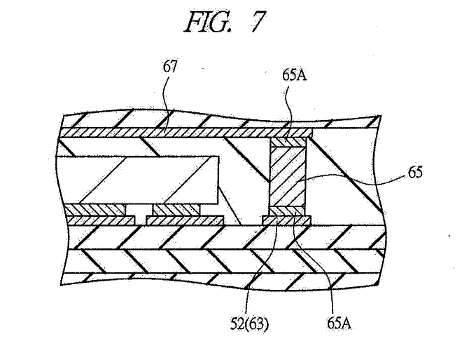

Next, examples of the structure and the material of the connecting member 65 will be described with reference to FIG. 7.

First, as shown in FIG. 7, the connecting member 65 with a columnar shape made of metal such as copper (Cu) is presented as an example of the connecting member 65. The both ends of the columnar connecting member 65 like this are connected to the board terminal 52 of the module board 51 and the board terminal 67 of the module board 66 by solders 65A. The Pb-free solder containing no Pb, for example, Sn-3Ag (silver)-0.5 Cu solder can be presented as an example of the solder 65A. The columnar connecting member 65 made of metal as described above is low in its manufacturing cost and has an advantage that the connecting process to the module boards 51 and 66 (board terminals 52 and 67) by the solder 65A is easy.

As the connecting member 65, for example, a solder ball having a core made of copper or resin, metal with a planar netlike shape, porous metal, a pin which has a spring mechanism and is inserted into a circuit board to be fixed by the spring mechanism, and a pin which is inserted into a circuit board to be fixed by solder can be used other than the columnar metal.

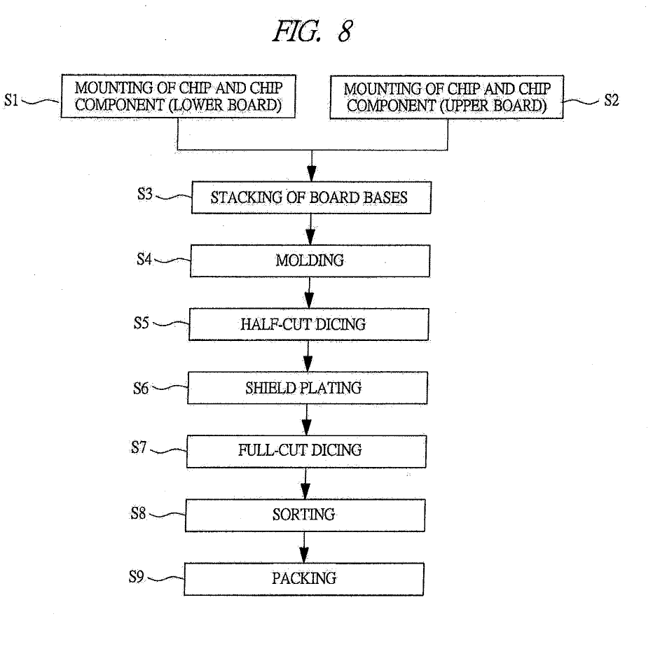

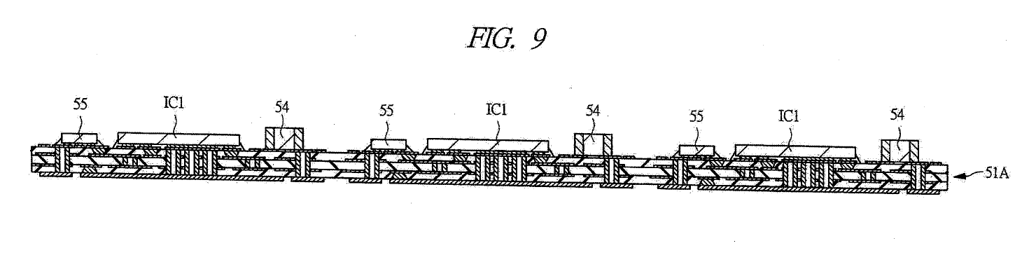

Next, an example of the manufacturing process of the module MA according to the first embodiment will be described in sequence with reference to FIG. 8 to FIG. 14. The example in which the columnar connecting member 65 (see FIG. 7) is used as the connecting member 65 will be described here. FIG. 8 is a flowchart for describing the manufacturing process of the module MA and FIG. 9 to FIG. 14 are cross-sectional views of the principal part in the manufacturing process showing three module regions.

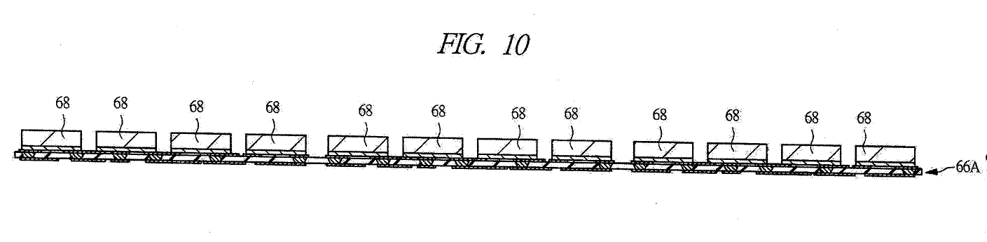

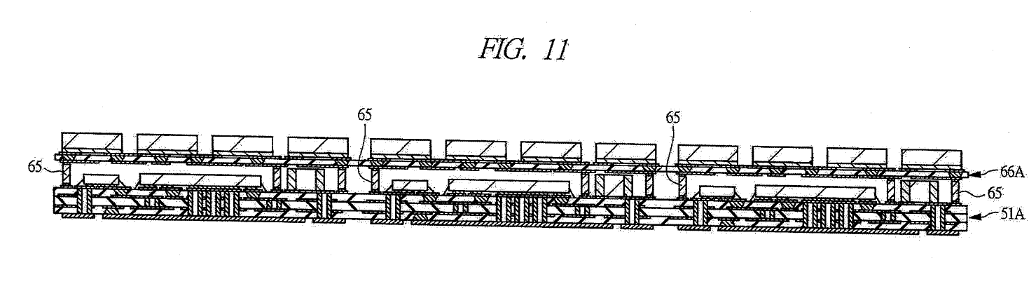

First, as shown in FIG. 9, a board base 51A partitioned into a plurality of regions to be the above-described module boards 51 (hereinafter, referred to as module regions) is prepared. Also, as shown in FIG. 10, a board base 66A partitioned into a plurality of regions to be the above-described module boards 66 (hereinafter, referred to as module regions) is prepared. These board bases 51A and 66A are multi-piece boards partitioned into a plurality of (for example, about 80) module regions defined by partition lines, and when 80 module regions are formed, each of the module region has the size of, for example, 90 mm×70 mm and the thickness of about 0.4 mm.

Next, in the board base 51A, the solder paste is printed on the outer-layer Cu wirings 63 (board terminals 52 (see FIG. 2)) to which the heat-generating semiconductor chip IC1, the single chip component 54 and the integrated chip component 55 are connected, and then, the heat-generating semiconductor chip IC1, the single chip component 54 and the integrated chip component 55 are disposed on the predetermined outer-layer Cu wirings 63. At this time, the heat-generating semiconductor chip IC1 and the integrated chip component 55 are disposed so that the bump electrodes BE formed on the element forming surface are faced to the outer-layer Cu wirings 63. Subsequently, by melting the solders by the reflow heating and the flux cleaning, the heat-generating semiconductor chip IC1, the single chip component 54 and the integrated chip component 55 are connected by solder at a time (Step S1). Similarly, in the board base 66A, the solder paste is printed on the board terminals 67 to which the integrated chip components 68 with a low upper temperature limit are connected, and then, the integrated chip components 68 with a low upper temperature limit are disposed on the predetermined board terminals 67. Subsequently, by melting the solders by the reflow heating and the flux cleaning, the integrated chip components 68 with a low upper temperature limit are connected by solder at a time (Step S2). The case where the solder paste is used has been described here, but the adhesive paste containing metal flakes can be used instead of the solder paste.

Next, as shown in FIG. 11, in the board base 51A, the solder paste is printed on the board terminals 52 to which the connecting members 65 are connected, and then, the connecting members 65 are disposed on the predetermined board terminals 52. Subsequently, by melting the solders by the reflow heating and the flux cleaning, the plurality of connecting members 65 are connected to the board terminals 52 by solder at a time. Next, in the board base 66A, the solder paste is printed on the board terminals 67 to which the connecting members 65 are connected, and then, the other ends of the plurality of connecting members 65 connected to the board base 51A are disposed on the predetermined board terminals 67. Subsequently, by melting the solders by the reflow heating and the flux cleaning, the plurality of connecting members 65 are connected to the board terminals 67 by solder at a time. Through the steps described above, the structure in which the board base 51A and the board base 66A are stacked via the plurality of connecting members 65 can be formed (step S3).

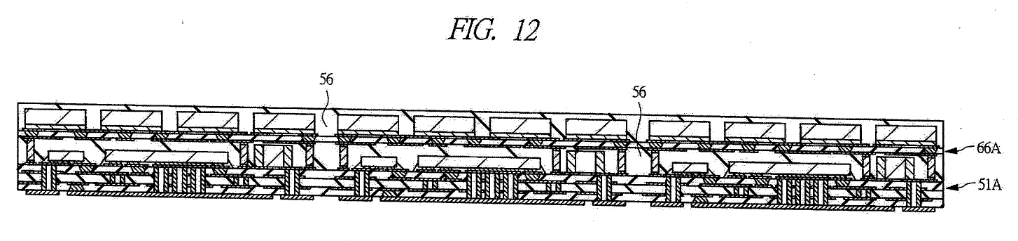

Next, as shown in FIG. 12, the transfer molding in which the component mounting surfaces of the board bases 51A and 66A (including the heat-generating semiconductor chips IC1, the single chip components 54, the integrated chip components 55 and the integrated chip components 68 with a low upper temperature limit) are sealed with mold resin 56 is performed (step S4). First, an upper die of a molding device is raised and the structural body in which the board base 51A and the board base 66A are stacked is placed on a lower die. Thereafter, the upper die is brought down to fix the structural body. The upper die is provided with air vents for discharging the air and the resin in the molding die between the upper die and the lower die to the outside. Subsequently, after the pressure in the molding die is forcibly reduced to, for example, 1 Torr or lower, the liquefied mold resin 56 obtained by heating resin tablets by a pre-heater to reduce the resin viscosity thereof is forced into the molding die. For example, thermosetting epoxy resin is used as the mold resin 56. Subsequently, after the sealing resin filled in the molding die is hardened by the polymerization reaction, the upper die and the lower die are opened to take out the structural body covered with the mold resin 56. Thereafter, the unnecessary sealing mold resin 56 is removed and then the baking treatment is performed to complete the polymerization reaction, whereby the components mounting surfaces of the board bases 51A and 66A are sealed with the mold resin 56.

By introducing the mold resin 56 after reducing the pressure in the molding die in the above-described manner, the fluidity of the mold resin 56 can be improved. Therefore, the mold resin 56 can be filled even in narrow spaces, for example, the space between the rear surface of the single chip component 54 and the component mounting surface of the board base 51A (about 10 μm) and the space between the main surface of the integrated chip component 55 and the component mounting surface of the board base 51A (about 10 to 20 μm) without forming the voids. As a result, even when the Pb-free solder is semi-molten by the heat at a temperature of about 260° C. applied in the assembly of the module MA described next, the flash flow of the Pb-free solder can be prevented, and therefore, the connection terminals on the both ends of the single chip component 54 or the connection terminals on the main surface of the integrated chip component 55 are not connected, and the short-circuit therebetween can be prevented.

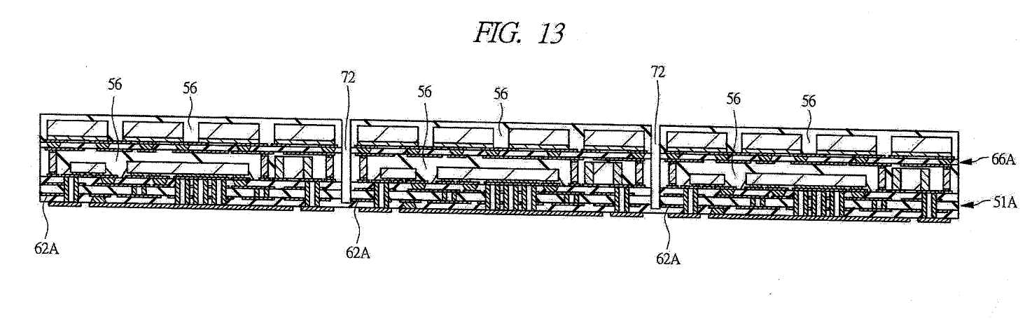

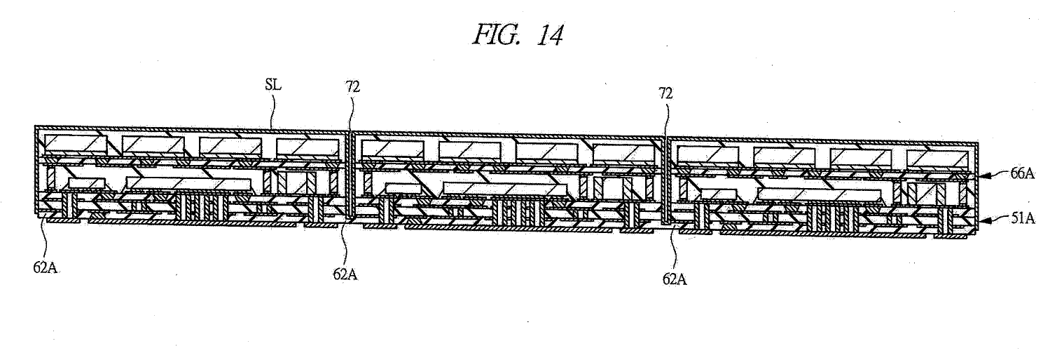

Next, as shown in FIG. 13, the mold resin 56 and the board bases 51A and 66A are half-diced along dicing lines (corresponding to the partition lines described above) by using a dicing cutter (step S5). The half dicing means the cutting to make notches 72 having a depth reaching the inner-layer Cu film 62A which is a part of the ground wiring provided in the lower board base 51A without completely cutting off the mold resin 56 and the board bases 51A and 66A, and the part below the inner-layer Cu film 62A remains connected. The inner-layer Cu film 62A used as the ground wiring is provided in the second layer wiring close to the component mounting surface of the board base 51A.

Thereafter, the trademark, product name, lot number and others are printed on the upper surface of the mold resin 56 for each module region.

Next, as shown in FIG. 14, the shield layer SL is formed by the electroless plating method so as to cover the surfaces of the inner-layer Cu film 62A and the mold resin 56 (upper and side surfaces) exposed in the notches 72 (step S6). The process of forming the shield layer SL will be described in sequence below.

(1) As a pre-etching process, the structural body is immersed in mixed solution of sodium hydroxide (20 g/L) and organic solvent (500 g/L) at 70° C. for 5 minutes and then rinsed with water.

(2) As a permanganate etching process, the structural body is immersed in mixed solution of potassium permanganate (50 g/L) and sodium hydroxide (20 g/L) at 80° C. for 5 minutes and then rinsed with water.

(3) As a neutralization process, the structural body is immersed in mixed solution of hydroxylamine (20 g/L) and concentrated sulfuric acid (50 ml/L) at 50° C. for 5 minutes and then rinsed with water.

(4) As a conditioning process, the structural body is immersed in ethanolamine (20 g/L) at 60° C. for 5 minutes and then rinsed with water.

(5) As a soft-etching process, the structural body is immersed in mixed solution of sodium persulfate (150 g/L) and concentrated sulfuric acid (10 ml/L) at 25° C. for 2 minutes and then rinsed with water.

(6) As a preliminary immersion process, the structural body is immersed in concentrated hydrochloric acid (300 ml/L) at a room temperature for 1 minute and then rinsed with water.

(7) As a catalytic process, the structural body is immersed in mixed solution of concentrated sulfuric acid (300 ml/L), palladium chloride (170 mg/L) and stannous chloride (10 g/L) at 25° C. for 3 minutes and then rinsed with water.

(8) As an acceleration process, the structural body is immersed in mixed solution of concentrated sulfuric acid (50 ml/L) and hydrazine (0.5 g/L) at 25° C. for 5 minutes and then rinsed with water.

(9) As an electroless Cu plating, the structural body is immersed in a plating bath in which mixed solution of copper sulfate (10 g/L), EDTA2Na (sodium ethylenediamine tetraacetic acid) (30 g/L), 37%-formaldehyde (3 ml/L), stabilizer (bipyridine or the like) (small amount) and polyethylene glycol is adjusted to have pH 12.2 by sodium hydroxide at 70° C. for 45 to 150 minutes and then rinsed with water.

(10) As a soft-etching process, the structural body is immersed in mixed solution of sodium peroxide (150 g/L) and concentrated sulfuric acid (10 ml/L) at 25° C. for 2 minutes and then rinsed with water.

(11) As an activation process, the structural body is immersed in concentrated sulfuric acid (100 ml/L) at a room temperature for 2 minutes and then rinsed with water.

(12) As a catalytic process, the structural body is immersed in mixed solution of palladium chloride (170 mg/L), concentrated hydrochloric acid (1 ml/L) and an additive agent (copper salt or the like) at 25° C. for 5 minutes and then rinsed with water.

(13) As an alkaline electroless Ni plating, the structural body is immersed in mixed solution of nickel sulfate (26 g/L), sodium citrate (60 g/L), sodium hypophosphite (21 g/L) and boric acid (30 g/L) (adjusted to have pH 8 to 9 by sodium hydroxide) at 90° C. for 5 to 18 minutes, rinsed with water and then dried at 150° C. for 60 minutes.

In the rinsing in each process, rinsing with running water for 2 minutes and rinsing with running pure water for 2 minutes are performed. By the film forming process described above, the shield layer SL made up of the stacked film of a Cu plating film and a Ni plating film is formed. Thereafter, the heating at 150° C. is performed for 1 hour. By this heating process, the pores from which hydrogen escapes and which are observed in the Ni plating film immediately after forming the shield layer SL are filled, and minute crystal grains are coagulated to be coarsened, thereby forming the Ni plating film with a smooth surface, and further forming a micro channel clack which is a structure with an air permeability. The Cu plating film has a function of blocking the electromagnetic wave, and the Ni plating film has an anticorrosion function. Also, the corrosion resistance of the Ni plating film is improved by the change of the surface crystal structure by the heat treatment. The thickness of the Cu plating film is preferably set within the range from 2 to 10 μm (it is needless to say that the thickness is not limited to this range depending on other conditions). Also, the range around the center value of 2.5 to 4 μm seems most preferable as the range suitable for mass production. The thickness of the Ni plating film is preferably set within the range from 0.1 to 0.3 μm (it is needless to say that the thickness is not limited to this range depending on other conditions). Also, the range around the center value of 0.25 μm seems most preferable as the range suitable for mass production. The micro channel crack is formed at random along the grain boundary in the shield layer SL, and the width of the micro channel crack on the surface of the Ni plating film is preferably set within the range of 100 nm or smaller (it is needless to say that the width is not limited to this range depending on other conditions). Also, the range from 1 to 60 nm seems preferable as the range suitable for mass production, and further the range around the center value of 30 nm seems most preferable. When the heat is applied up to 260° C. in view of the reflow process, the width of the micro channel crack is expanded, but this width is 100 nm or smaller. The crack width in the Cu plating film is smaller than that on the surface of the Ni plating film.

Next, the board base 51A below the notches 72 is further cut and separated into individual modules MA (step S7). Next, electrical characteristics of the modules MA are measured based on the product specifications to sort the modules MA (step S8), and then, the good modules MA are packed (step S9).

Next, the mounting process of the module MA will be described.

As described above, the electrodes 53G and 53S for solder connection are formed on the rear surface of the module board 51 so as to be mounted on the mother board. First, solder paste is printed on the mother board. Subsequently, after disposing the module MA on the mother board, the reflow heating at the temperature of, for example, 250° C. or higher is performed, thereby mounting the module mA on the mother board 66 via the solder. Then, after the test of the electrical characteristics is performed, the mounting process is completed.

In the present embodiment, the case where the surface mounted components mounted on the module board 51 are covered with the highly elastic mold rein 56 has been described, but the present invention is not limited to this and resin with low elasticity, for example, silicon resin can also be used for the mold resin 56.

Furthermore, the case where the present invention is applied to the dual band system capable of supporting the radio waves of two frequency bands of GSM 900 and GSM 1800 has been described, but the present invention is not limited to this and it can be applied to the triple band system capable of supporting the radio waves of the three frequency bands of GSM 900, GSM 1800 and GSM 1900. Also, it can support 800 MHz band and 850 MHz band.

As described above, according to the present embodiment, in a system of a digital mobile phone, even when the module MA has the heat-generating semiconductor chip IC1 in which a surface mounted component which generates electromagnetic waves such as a power amplifier PM is formed, the shield layer SL made up of the stacked film of a Cu film and a Ni film formed by the electroless plating method on the surfaces (upper and side surfaces) of the mold resin 56 covering the surface mounted component is formed, and the shield layer SL and the ground wiring are electrically connected to achieve sufficient electromagnetic wave shielding effect, and by this means, the electromagnetic waves generated from the power amplifier PM can be blocked by the shield layer SL.

Also, the micro channel crack with a width of 100 nm or smaller (typically 1 to 60 nm) is formed along the crystal grain boundary in the shield layer SL made up of the stacked film of a Cu film and a Ni film formed by the electroless plating method, and the micro channel crack reaches the mold resin 56 from the surface of the shield layer SL. Therefore, even when the moisture contained in the mold resin 56, the moisture contained in the module board 51 or the moisture entering into the interface between the module board 51 and the mold resin 56 is evaporated, the water vapor can be discharged to the outside of the module MA through the micro channel crack. As a result, since the volume expansion does not occur even when the moisture is evaporated by the reflow heating and others, the peeling of the shield layer SL can be prevented.

Further, by forming the shield layer SL made up of the stacked film of a Cu film and a Ni film by the electroless plating method, the shield layer SL with good spreadability can be obtained. As a result, even when the deformation occurs in the reflow heating and the actual operation of the module MA due to the difference in the linear expansion coefficient between the shield layer SL and other component materials, the occurrence of the breakage and the cracking in the shield layer SL due to the stress concentration can be suppressed. From the foregoing, the module MA having a shielding effect to the electromagnetic wave and a high reliability to the reflow heating can be provided.

Furthermore, in the embodiment shown in the structural drawing, the high power amplifier module is operated and kept in a steady state, and then, the thermal simulation of the whole module is carried out. As a result, it is confirmed that the temperature of the integrated chip component 68 with a low upper temperature limit is lower than its upper temperature limit (for example, the thermal separation of about 20° C. can be achieved between the operation temperature of the high power amplifier and the SAW filter).

### Second Embodiment

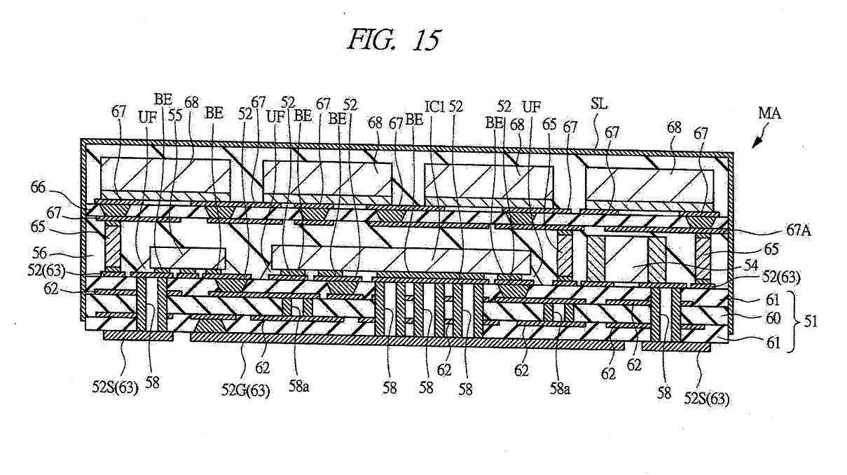

Next, a module MA according to the second embodiment will be described with reference to FIG. 15.

As shown in FIG. 15, in the module MA of the second embodiment, a part of the board terminal 67 (shown as board terminal 67A) is formed to reach the outer periphery of the module board 66 and is electrically connected to the shield layer SL. This board terminal 67A electrically connected to the shield layer SL is the ground wiring. The module MA of the second embodiment with the above-described structure can also achieve the same effects as those of the module MA of the first embodiment.

### Third Embodiment

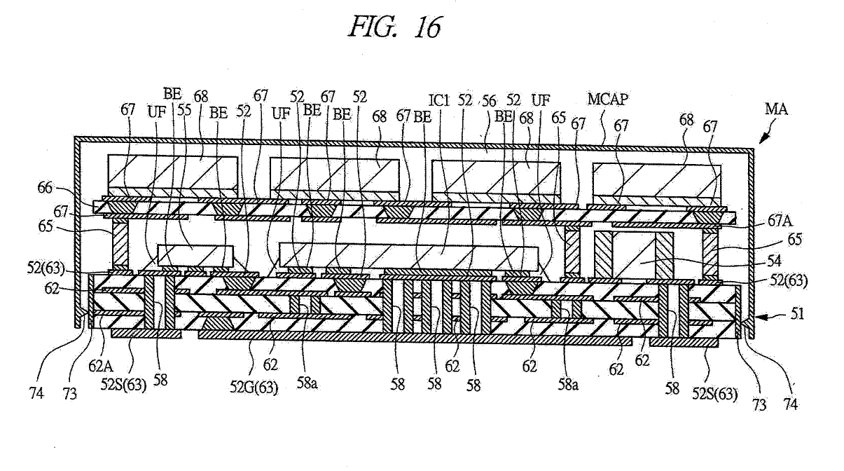

Next, a module MA according to the third embodiment will be described with reference to FIG. 16.

As shown in FIG. 16, in the module MA of the third embodiment, the sealing structure by the mold resin 56 and the electromagnetic wave shield structure by the shield layer SL are omitted, and the sealing structure and the electromagnetic wave shield structure using a metal cap MCAP are employed. Cu films 73 connected to the inner-layer Cu film 62A which is the ground wiring are formed on the side surfaces of the module board 51. Also, protrusions 74 which come into contact with the Cu films 73 on the side surfaces of the module board 51 when the metal cap MCAP is engaged with the structural body made up of the module boards 51 and 66 are formed in the metal cap MCAP, and by making the protrusions 74 come into contact with the Cu films 73 electrically connected to the ground wiring, the electromagnetic wave shield structure by the metal cap MCAP is realized.

The Cu film 73 described above may be provided on the side surface of the module board 66, and in such a case, the board terminal 67A which is the ground wiring described in the second embodiment is provided in the module board 66A to have the structure in which the board terminal 67A and the Cu film 73 are connected. Also in the case of this structure, the protrusions 74 are formed at the positions where the protrusions 74 of the metal cap MCAP are in contact with the Cu films 73 on the side surfaces of the module board 66 when the metal cap MCAP is engaged with the structural body made up of the module boards 51 and 66.

In the module MA of the third embodiment described above, the mold resin 56 is omitted, and therefore, the manufacturing process of the module MA can be simplified. Also, since the electromagnetic wave shield structure is realized by engaging the metal cap MCAP, the electromagnetic wave shield structure can be easily and simply realized compared with the case where the shield layer SL is formed by the electroless plating method.

Also in the module MA of the third embodiment with the structure described above, the same effects as those of the modules MA of the first and second embodiments can be achieved.

### Fourth Embodiment

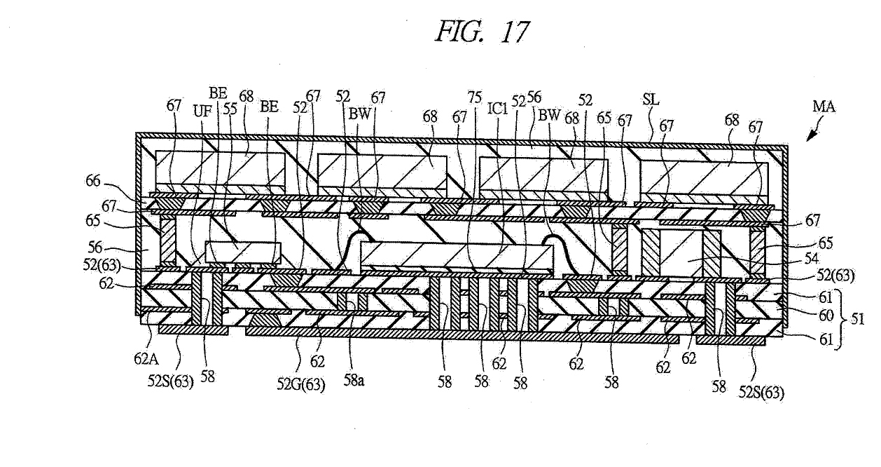

Next, a module MA according to the fourth embodiment will be described with reference to FIG. 17.

As shown in FIG. 17, in the module MA of the fourth embodiment, the heat-generating semiconductor chip IC1 is mounted on the module board 51 with the rear surface thereof being faced to the module board 51, and is fixed to the predetermined board terminal 52 by an adhesive material 75 such as DAF (Die Attach Film). Further, a plurality of external terminals formed on the main surface (element forming surface) of the heat-generating semiconductor chip IC1 are connected to the corresponding board terminals 52 of the module board 51 by a bonding material. Here, bonding wires BW made of thin lines of Au are used as the bonding material.

Furthermore, since the bonding wires BW are used for the heat-generating semiconductor chip IC1, a plating film is formed on the surfaces of all board terminals 52. The plating film is made up of a stacked film of, for example, a Ni layer and an Au layer formed in this order from below by the plating method. Therefore, the single chip component 54 is connected to the plating film with solder by the connection terminal thereof, the integrated chip component 55 is connected to the plating film by the connection terminal thereof, and the bonding wires BW connected to the external terminals formed on the main surface of the heat-generating semiconductor chip IC1 are connected to the plating films on the surfaces of the board terminals 52.

The structure of the module MA of the fourth embodiment other than that described above is almost the same as that of the module MA of the first embodiment.

The module MA of the fourth embodiment with the structure described above can also achieve the same effects as those of the module MA of the first embodiment.

### Fifth Embodiment

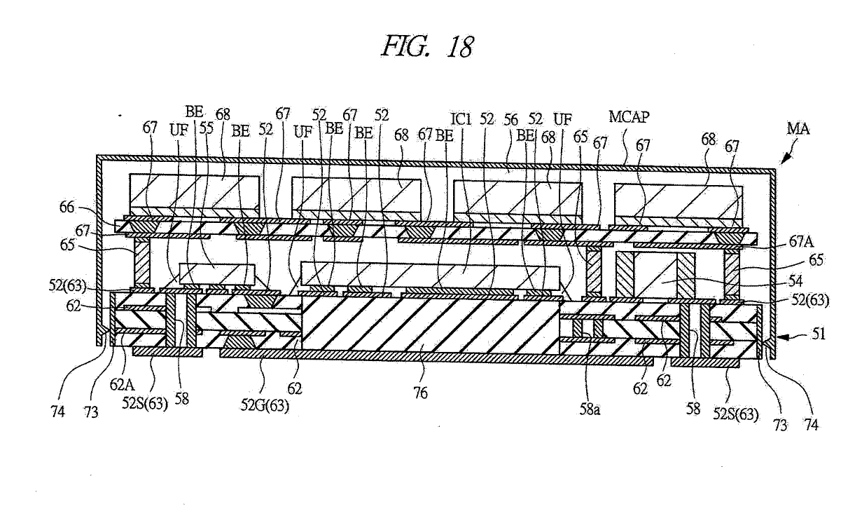

Next, a module MA according to the fifth embodiment will be described with reference to FIG. 18.

As shown in FIG. 18, in the module MA of the fifth embodiment, heat dissipation metal 76 is embedded in a through hole forming area of the lower module board 51 to which the heat-generating semiconductor chip IC1 is connected. By this means, the heat generated in the heat-generating semiconductor chip IC1 is efficiently dissipated to the board, and by connecting the heat dissipation metal 76 to the mother board of a mobile phone by solder or a heat dissipation member such as a heat dissipation sheet, the good thermal separation effect can be achieved.

The structure of the module MA of the fifth embodiment other than that described above is almost the same as that of the module MA of the first embodiment.

The module MA of the fifth embodiment with the structure described above can also achieve the same effects as those of the module MA of the first embodiment.

### Sixth Embodiment

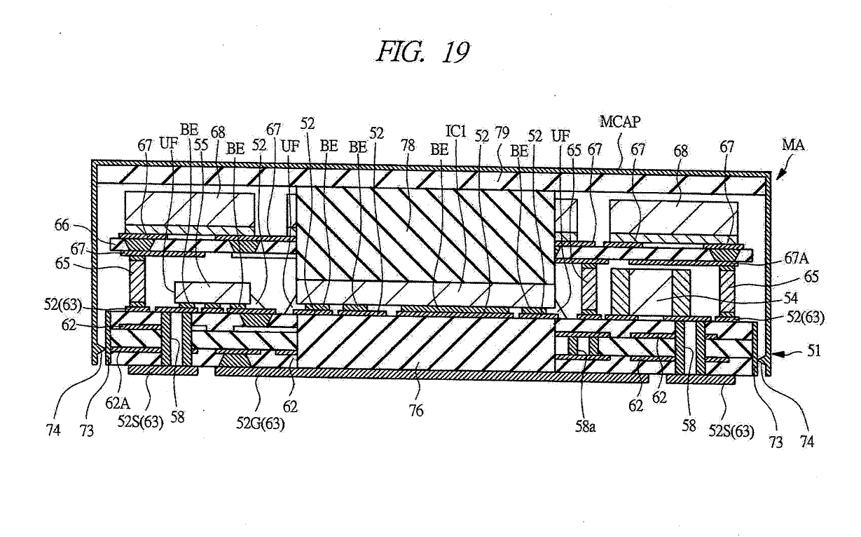

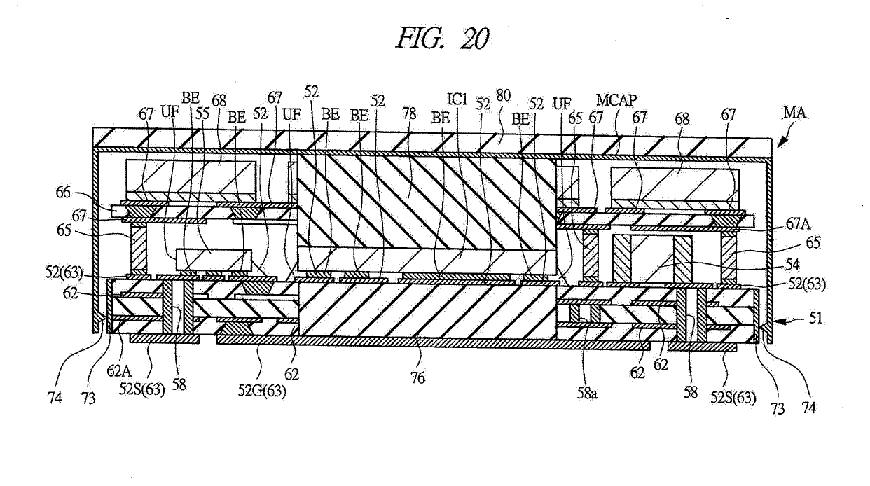

Next, a module MA according to the sixth embodiment will be described with reference to FIG. 19.

As shown in FIG. 19, in the module MA of the sixth embodiment, heat dissipation metal 76 is embedded in a through hole forming area of the lower module board 51 to which the heat-generating semiconductor chip IC1 is connected. By this means, the heat generated in the heat-generating semiconductor chip IC1 is efficiently dissipated to the board, and by connecting the heat dissipation metal 76 to the mother board of a mobile phone by solder or a heat dissipation member such as a heat dissipation sheet, the good thermal separation effect can be achieved.

In addition, one or more layers of a heat dissipation member 78 are disposed on the heat-generating semiconductor chip IC1 by such methods as adhesion, solder fixation and contacting. For the greater effect, a heat dissipation member 79 is further disposed on the heat dissipation member 78 on the heat-generating semiconductor chip IC1 by such methods as adhesion, solder fixation and contacting so as to diffuse the heat within a range that does not affect the filter, thereby achieving the good thermal separation effect. In this structure, only the heat dissipation member 78 may be used, and the heat dissipation member 79 may be used together on the heat dissipation member 78.

The structure of the module MA of the sixth embodiment other than that described above is almost the same as that of the module MA of the fifth embodiment.

The module MA of the sixth embodiment with the structure described above can also achieve the same effects as those of the module MA of the first embodiment.

### Seventh Embodiment

Next, a module MA according to the seventh embodiment will be described with reference to FIG. 20.

As shown in FIG. 20, in the module MA of the seventh embodiment, heat dissipation metal 76 is embedded in a through hole forming area of the lower module board 51 to which the heat-generating semiconductor chip IC1 is connected. By this means, the heat generated in the heat-generating semiconductor chip IC1 is efficiently dissipated to the board, and by connecting the heat dissipation metal 76 to the mother board of a mobile phone by solder or a heat dissipation member such as a heat dissipation sheet, the good thermal separation effect can be achieved.

In addition, one or more layers of a heat dissipation member 78 are disposed on the heat-generating semiconductor chip IC1 by such methods as adhesion, solder fixation and contacting. For the greater effect, a heat dissipation member 80 is disposed on an upper outside part of the module (may be disposed on end portion or side surface) by such methods as adhesion, solder fixation and contacting so as to diffuse the heat within a range that does not affect the filter, thereby achieving the good thermal separation effect.

The structure of the module MA of the seventh embodiment other than that described above is almost the same as that of the module MA of the sixth embodiment.

The module MA of the seventh embodiment with the structure described above can also achieve the same effects as those of the module MA of the first embodiment.

### Eighth Embodiment

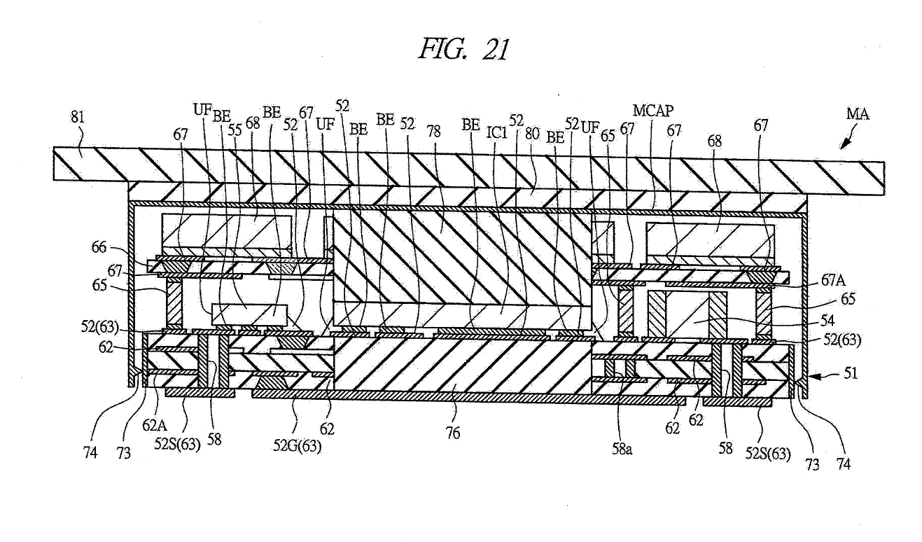

Next, a module MA according to the eighth embodiment will be described with reference to FIG. 21.

As shown in FIG. 21, in the module MA of the eighth embodiment, heat dissipation metal 76 is embedded in a through hole forming area of the lower module board 51 to which the heat-generating semiconductor chip IC1 is connected. By this means, the heat generated in the heat-generating semiconductor chip IC1 is efficiently dissipated to the board, and by connecting the heat dissipation metal 76 to the mother board of a mobile phone by solder or a heat dissipation member such as a heat dissipation sheet, the good thermal separation effect can be achieved.

In addition, one or more layers of a heat dissipation member 78 are disposed on the heat-generating semiconductor chip IC1 by such methods as adhesion, solder fixation and contacting. For the greater effect, a heat dissipation member 80 is disposed on an upper outside part of the module (may be disposed on end portion or side surface) by such methods as adhesion, solder fixation and contacting. Furthermore, by disposing the heat dissipation member 80 on a part of a chassis 81 of a mobile phone by such methods as adhesion, solder fixation and contacting to diffuse the heat within a range that does not affect the filter, the good thermal separation effect can be achieved.

The structure of the module MA of the eighth embodiment other than that described above is almost the same as that of the module MA of the sixth embodiment.

The module MA of the eighth embodiment with the structure described above can also achieve the same effects as those of the module MA of the first embodiment.

In the foregoing, the invention made by the inventors of the present invention has been concretely described based on the embodiments. However, it is needless to say that the present invention is not limited to the foregoing embodiments and various modifications and alterations can be made within the scope of the present invention.

The semiconductor device and the manufacturing method thereof of the present invention can be applied to a semiconductor device having a structure in which a plurality of semiconductor chips and chip components are mounted and a manufacturing process thereof.

What is claimed is:

1. A semiconductor device comprising:
a first circuit board in which a wiring layer in a part of an inner-layer wiring is used as a ground wiring;
a plurality of first mounted components mounted on a first component mounting surface of the first circuit board;
a second circuit board stacked on the first component mounting surface of the first circuit board;
a plurality of second mounted components mounted on a second component mounting surface of the second circuit board;
a plurality of connecting members which mechanically and electrically connect the first circuit board and the second circuit board; and
first resin which seals the first circuit board, the second circuit board, the plurality of first mounted components and the plurality of second mounted components together,
wherein the plurality of first mounted components include a first component which generates heat, the plurality of second mounted components include a second component whose characteristics are changed by the heat generated from the first component, and the first component and the second component are disposed so as to be thermally separated.

2. The semiconductor device according to claim 1,
wherein each of the plurality of connecting members is columnar metal, a solder ball having a core made of copper or resin, metal with a planar netlike shape, porous metal, a first pin which has a spring mechanism and is inserted into at least one of the first circuit board and the second circuit board to be fixed by the spring mechanism, or a second pin which is inserted into at least one of the first circuit board and the second circuit board to be fixed by solder.

3. The semiconductor device according to claim 1, further comprising:
a shield member which is electrically connected to the ground wiring and shields the first circuit board, the second circuit board, the plurality of first mounted components and the plurality of second mounted components from electromagnetic waves from outside.

4. The semiconductor device according to claim 1,
wherein the plurality of first mounted components and the plurality of second mounted components are made up of one or more semiconductor chips and one or more chip components,
the semiconductor chip has a front surface and a rear surface on a reverse side of the front surface and a plurality of protruding electrodes connected to the first circuit board or the second circuit board are formed on the front surface, and
the semiconductor chip is mounted with the front surface thereof being faced with the first circuit board or the second circuit board.

5. The semiconductor device according to claim 1,
wherein the plurality of first mounted components and the plurality of second mounted components are made up of one or more semiconductor chips and one or more chip components,
the semiconductor chip has a front surface and a rear surface on a reverse side of the front surface and is mounted with the rear surface thereof being faced with the first circuit board or the second circuit board, and
a plurality of wires for electrically connecting the semiconductor chip and the first circuit board or the second circuit board are provided.

6. A semiconductor device comprising:
a first circuit board in which a wiring layer in a part of an inner-layer wiring is used as a ground wiring;
a plurality of first mounted components mounted on a first component mounting surface of the first circuit board;
a second circuit board stacked on the first circuit board;
a plurality of second mounted components mounted on a second component mounting surface of the second circuit board; and
a plurality of connecting members which mechanically and electrically connect the first circuit board and the second circuit board,
wherein the plurality of first mounted components include a first component which generates heat, the plurality of second mounted components include a second component whose characteristics are changed by the heat generated from the first component, and the first component and the second component are disposed so as to be thermally separated,
the plurality of first mounted components and the plurality of second mounted components are made up of one or more semiconductor chips and one or more chip components,
the semiconductor chip has on its front surface a plurality of protruding electrodes connected to the first circuit board or the second circuit board,
the semiconductor chip is mounted with the front surface thereof, being faced with the first circuit board or the second circuit board, and
a space between the semiconductor chip and the first circuit board or the second circuit board is sealed with second resin.

7. The semiconductor device according to claim 6, further comprising:
a shield member which is electrically connected to the ground wiring and shields the first circuit board, the second circuit board, the plurality of first mounted components and the plurality of second mounted components from electromagnetic waves from outside.

8. A semiconductor device comprising:
a first circuit board;
a plurality of first mounted components mounted on a first component mounting surface of the first circuit board;
a second circuit board which is stacked on the first component mounting surface of the first circuit board and in which a wiring layer in a part of an inner-layer wiring is used as a ground wiring;
a plurality of second mounted components mounted on a second component mounting surface of the second circuit board;
a plurality of connecting members which mechanically and electrically connect the first circuit board and the second circuit board; and
first resin which seals the first circuit board, the second circuit board, the plurality of first mounted components and the plurality of second mounted components together,
wherein the plurality of first mounted components include a first component which generates heat, the plurality of second mounted components include a second component whose characteristics are changed by the heat generated from the first component, and the first component and the second component are disposed so as to be thermally separated.

9. The semiconductor device according to claim 8, further comprising:
a shield member which is electrically connected to the ground wiring and shields the first circuit board, the second circuit board, the plurality of first mounted components and the plurality of second mounted components from electromagnetic waves from outside.

10. A semiconductor device comprising:
a first circuit board;
a plurality of first mounted components mounted on a first component mounting surface of the first circuit board;
a second circuit board which is stacked on the first circuit board and in which a wiring layer in a part of an inner-layer wiring is used as a ground wiring;
a plurality of second mounted components mounted on a second component mounting surface of the second circuit board; and
a plurality of connecting members which mechanically and electrically connect the first circuit board and the second circuit board,
wherein the plurality of first mounted components include a first component which generates heat, the plurality of second mounted components include a second component whose characteristics are changed by the heat generated from the first component, and the first component and the second component are disposed so as to be thermally separated,
the plurality of first mounted components and the plurality of second mounted components are made up of one or more semiconductor chips and one or more chip components,
the semiconductor chip has on its front surface a plurality of protruding electrodes connected to the first circuit board or the second circuit board,
the semiconductor chip is mounted with the front surface thereof being faced with the first circuit board or the second circuit board, and
a space between the semiconductor chip and the first circuit board or the second circuit board is sealed with second resin.

11. A manufacturing method of a semiconductor device comprising the steps of:
(a) preparing a first board base in which a wiring layer in a part of an inner-layer wiring is used as a ground wiring and one or more structures including a heat dissipation via, a heat dissipation metal body and a heat dissipation metal core layer are formed in a first circuit board, the first board base being partitioned into a plurality of the first circuit boards;
(b) mounting a plurality of first mounted components on a first component mounting surface of the first circuit board;
(c) preparing a second board base partitioned into a plurality of second circuit boards each having the same planar shape as that of the first circuit board;
(d) mounting a plurality of second mounted components on a second component mounting surface of the second circuit board;
(e) after the step (b) and after the step (d), mechanically and electrically connecting the first board base and the second board base via a plurality of connecting members so that the second circuit board is stacked on the first component mounting surface of the first circuit board;
(f) after the step (e), sealing the first board base, the second board base, the plurality of first mounted components and the plurality of second mounted components together with first resin;
(g) dicing the first resin, the first board base and the second board base along the shape of the first circuit board and the second circuit board until the first board base is partially cut in a thickness direction, thereby forming trenches having side surfaces on which the ground wirings are exposed;
(h) forming a metal shield member so as to cover the side surfaces of the trenches and the first resin and come into contact with the ground wirings; and
(i) after the step (h), dicing the remaining first base body along the trenches, thereby dividing it into individual semiconductor devices.

12. The manufacturing method of the semiconductor device according to claim 11,
wherein the shield member is formed by a plating method.

13. The manufacturing method of the semiconductor device according to claim 11,
wherein the plurality of connecting members are made of porous metal.

14. A manufacturing method of a semiconductor device comprising the steps of:
(a) preparing a first board base in which a wiring layer in a part of an inner-layer wiring is used as a ground wiring and one or more structures including a heat dissipation via, a heat dissipation metal body and a heat dissipation metal core layer are formed in a first circuit board, the first board base being partitioned into a plurality of the first circuit boards;
(b) mounting a plurality of first mounted components on a first component mounting surface of the first circuit board;
(c) preparing a second board base partitioned into a plurality of second circuit boards each having the same planar shape as that of the first circuit board;
(d) mounting a plurality of second mounted components on a second component mounting surface of the second circuit board;
(e) after the step (b) and after the step (d), mechanically and electrically connecting the first board base and the second board base via a plurality of connecting members so that the second circuit board is stacked on the first component mounting surface of the first circuit board;
(f) dicing the first board base and the second board base along the shape of the first circuit board and the second circuit board, thereby dividing them into individual semiconductor devices; and
(g) attaching a shield member having a cap shape, which covers side and upper surfaces of each semiconductor device and is electrically connected to the ground wiring, to each of the semiconductor devices,
wherein the plurality of first mounted components and the plurality of second mounted components are made up of one or more semiconductor chips and one or more chip components,
the semiconductor chip has on its front surface a plurality of protruding electrodes connected to the first circuit board or the second circuit board,
the semiconductor chip is mounted with the front surface thereof being faced with the first circuit board or the second circuit board,
in the step (b) and the step (d), a space between the semiconductor chip and the first circuit board or the second circuit board is sealed with second resin, and
the shield member has protrusions to be in contact with side surfaces of each individual semiconductor device, and the protrusions come into contact with the ground wiring exposed on the side surface of each individual semiconductor device.
